(19) United States
(12) Patent Application Publication
(10) Pub. No.: US 2025/0113514 A1
(43) Pub. Date: Apr. 3, 2025

(54) METHOD FOR PRODUCING A POWER SEMICONDUCTOR COMPONENT HAVING A PLURALITY OF FINS AND POWER SEMICONDUCTOR COMPONENT PRODUCED THEREFROM

(71) Applicant: Robert Bosch GmbH, Stuttgart (DE)

(72) Inventors: Daniel Krebs, Aufhausen (DE); Jens Baringhaus, Sindelfingen (DE)

(21) Appl. No.: 18/887,371

(22) Filed: Sep. 17, 2024

(30) Foreign Application Priority Data
Sep. 29, 2023 (DE) 102023209573.4

(51) Int. Cl. H01L 29/66; H01L 21/02; H01L 21/308; H01L 29/16; H01L 29/20; H01L 29/775

(52) U.S. Cl. CPC H10D 30/014; H01L 21/0217; H01L 21/02236; H01L 21/02241; H01L 21/02255; H01L 21/3086; H10D 30/43; H10D 62/8325; H10D 62/8503

(57) ABSTRACT

A method for producing a power semiconductor component having a plurality of fins. The method includes: creating a plurality of mesas starting from a front side of a semiconductor substrate into a drift layer of the semiconductor substrate by means of etching, each mesa being arranged between a first trench and a second trench. Each mesa has a width greater than 500 nm. The method further includes applying a mask layer to the top side, the first side surface, the second side surface, the first trench bottom surface and the second trench bottom surface; creating a structured mask by removing the mask layer in certain regions, so that an exposed surface is created; creating fins by machining the exposed surface; removing the structured mask and completing the power semiconductor component.

### FIELD

The present invention relates to a method for producing a power semiconductor component having a plurality of fins and a power semiconductor component having a plurality of fins.

### BACKGROUND INFORMATION

Power semiconductor components that have a fin structure and comprise a wide-bandgap substrate provide high channel density and minimal on-resistance in power electronics. The fins have a small width of less than 500 nm. The fins are produced by narrowing the mesas on both sides.

A disadvantage here is that the surface quality of the fin side walls is negatively affected. In the case of a SiC substrate, carbon clusters can form on the fin side walls, which lead to a reduction in channel mobility, since charge carriers exhibit increased scattering at these defects.

Another disadvantage is that the transconductance is very steep, so that problems can arise in the dynamic operation of the power semiconductor component. For example, parasitic switching on of a transistor in a half-bridge configuration occurs.

An object of the present invention is to overcome these disadvantages.

### SUMMARY

A method according to an example embodiment of the present invention for producing a power semiconductor component having a plurality of fins includes creating a plurality of mesas starting from a front side of a semiconductor substrate into a drift layer of the semiconductor substrate by means of etching, wherein each mesa comprises a top side that corresponds to a region of the front side of the semiconductor substrate, and each mesa is arranged between a first trench and a second trench, wherein the first trench comprises a first trench bottom surface and the second trench comprises a second trench bottom surface, wherein each mesa comprises a first side surface and a second side surface, wherein the first side surface corresponds to a first trench side surface of the first trench and the second side surface corresponds to a second trench side surface of the second trench, wherein each mesa has a width greater than 500 nm, and applying a mask layer to the top side, the first side surface, the second side surface, the first trench bottom surface and the second trench bottom surface. The method further comprises creating a structured mask by means of removing the mask layer in certain regions, so that an exposed surface is created, wherein the exposed surface comprises the first side surface, the top side in certain regions and the first trench bottom surface, and creating fins by machining the exposed surfaces. The method further comprises removing the structured mask and completing the power semiconductor component.

An advantage here is that the fins are only narrowed on one side. As a result, the first side surface of the fin comprises a different interface structure than the second side surface of the fin, resulting in high channel density and flat transconductance.

In a further development of the present invention, the semiconductor substrate comprises SiC.

In a further embodiment of the present invention, the mask layer comprises SiN.

An advantage here is that SiN has a high degree of resistance to oxidation processes and can thus be used as a mask in order to prevent the thermal growth of an oxide layer on a part of the semiconductor surface.

In a further development of the present invention, the fins are created by means of thermal oxidation.

In a further embodiment of the present invention, the semiconductor substrate comprises GaN.

In a further development of the present invention, the mask layer comprises Ti or TiO2.

In a further embodiment of the present invention, the fins are created by means of TMAH.

The power semiconductor component according to the present invention having a plurality of fins is produced by means of the method according to the present invention.

In one embodiment of the present invention, the power semiconductor component is a FinFET.

In a further embodiment of the present invention, the power semiconductor component is a FinMOSFET.

Further advantages of the present invention can be found in the following description of exemplary embodiments and the rest of the disclosure herein.

### BRIEF DESCRIPTION OF THE DRAWINGS

The present invention is explained below with reference to preferred embodiments and the figures.

FIG. 1 shows the method according to an example embodiment of the present invention for producing a power semiconductor component having a plurality of fins.

FIG. 2A shows a starting product of the method according to an example embodiment of the present invention.

FIG. 2B-2E show intermediate products of the individual method steps of the method according to the present invention.

FIG. 3 shows a power semiconductor component produced according to an example embodiment of the present invention.

### DETAILED DESCRIPTION OF EXAMPLE EMBODIMENTS

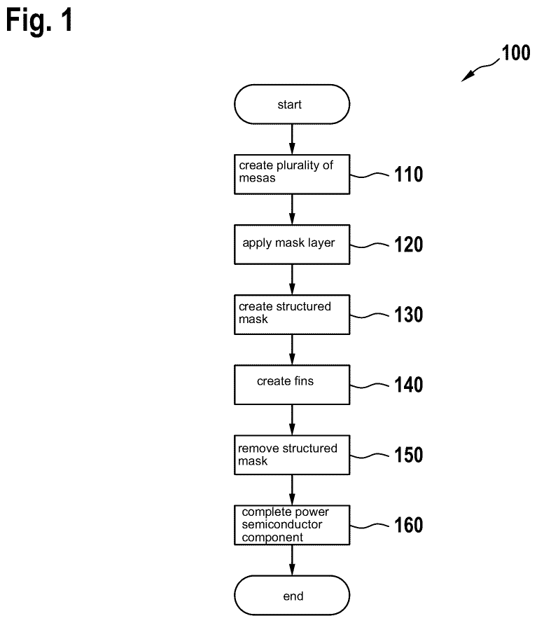

FIG. 1 shows the method 100 according to the present invention for producing a power semiconductor component having a plurality of fins. The method 100 starts with a step 110, in which a plurality of mesas are created starting from a front side of a semiconductor substrate into a drift layer of the semiconductor substrate by means of etching. In this connection, the term “mesa” refers to an elevation having a flat surface and steep flanks. Each mesa comprises a top side that corresponds to or coincides with a region of the front side of the semiconductor substrate. Each mesa is arranged between a first trench and a second trench, wherein the first trench comprises a first trench bottom surface and the second trench comprises a second trench bottom surface. Each mesa comprises a first side surface and a second side surface, wherein the first side surface corresponds to a first trench side surface of the first trench and the second side surface corresponds to a second trench side surface of the second trench. Each mesa has a width greater than 500 nm. In a following step 120, a mask layer is applied to the top side, the first side surface, the second side surface, the first trench bottom surface and the second trench bottom surface. In a subsequent step 130, a structured mask is created by removing the mask layer in certain regions. This creates an exposed surface that comprises the first side surface, the top side in certain regions and the first trench bottom surface. In a subsequent step 140, fins are created by machining the exposed surface. In a subsequent step 150, the structured mask is removed and subsequently the power semiconductor component is completed in a step 160. The step 160 comprises a plurality of method steps from the related art. In other words, the mesas are narrowed on one side, resulting in fins being created with different interface structures on the side walls.

The semiconductor substrate comprises, for example, SiC or GaN. If the semiconductor substrate is SiC, SiN, for example, is used as a mask layer. In step 140, for example, thermal oxidation is used to create the fins. In the case of GaN, Ti or TiO2 is used as a mask layer. In step 140, for example, TMAH is then used to create the fins.

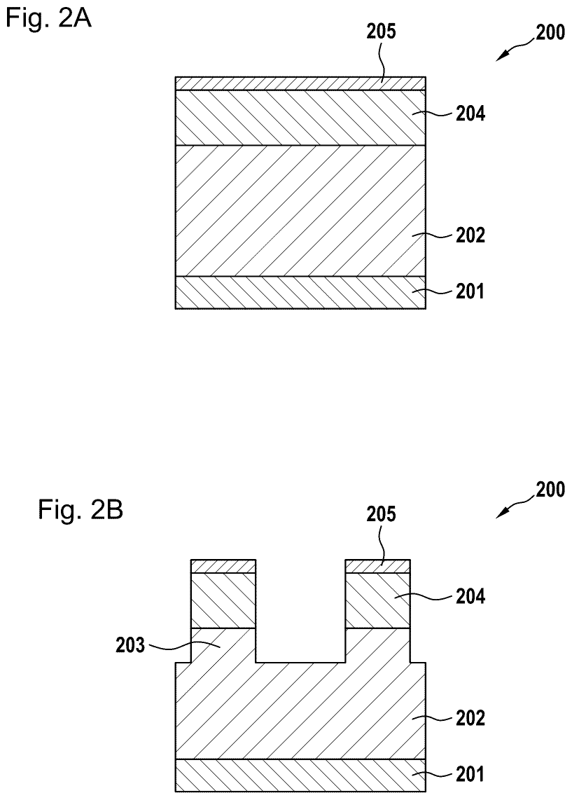

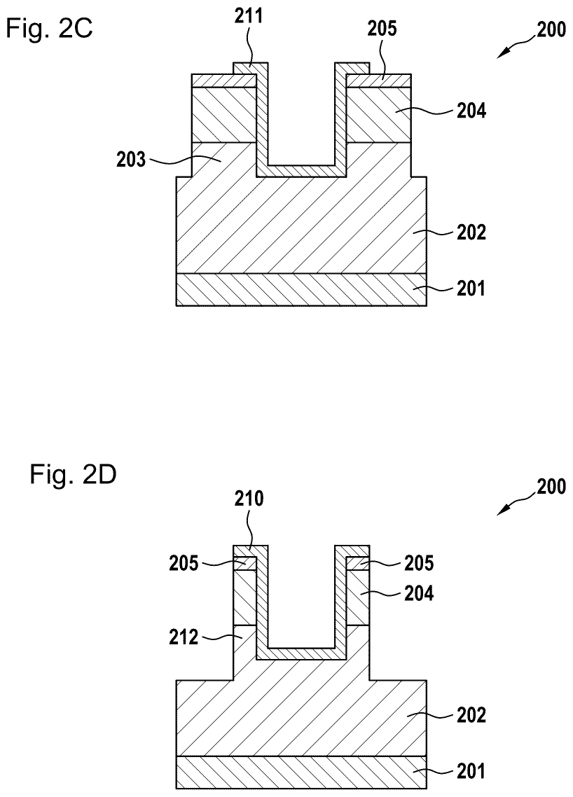

FIG. 2A shows the starting product 200 of the method 100 according to the present invention from FIG. 1. The power semiconductor component produced based on the starting product is a FinMOSFET. The starting product 200 comprises a semiconductor substrate 201, in particular n-conductive. A drift layer 202 is arranged on the semiconductor substrate 201. A channel region 204, in particular a p-channel, is arranged on the drift layer 202. A source region layer 205 is arranged on the channel region 204. The semiconductor substrate 201 comprises, for example, SiC or GaN.

FIG. 2B shows the intermediate product 210 of the method step 110 from FIG. 1. It should be noted that the same reference numbers describe the same features. FIG. 2B shows two mesa structures 203, which are separated from one another by a second trench 207. The first trenches 206 can be seen in the edge region.

FIG. 2C shows the intermediate product 230 of the method step 130 from FIG. 1. In addition to the features described in FIG. 2A and 2B, a structured mask 211 is shown. The structured mask 211 covers in certain regions a top side of the mesas 203 and a second trench bottom surface of the second trench 207, along with second side surfaces of the mesas. In other words, first side surfaces, regions of the top side and first trench bottom surfaces are exposed and form an exposed surface.

FIG. 2D shows the intermediate product 240 of the method step 140 from FIG. 1. The mesa structures 203 are narrowed to form fins 212. In each case, one side wall of the fin 212, i.e. the second side surface, is protected by the structured mask 211. This means that for producing the fins 212, the final width of the fins 212 is created only over one side surface of the mesas 203. In the example shown here, the narrowing for the left fin 212 is effected from the left and for the right fin 212 from the right. In other words, the inner side walls of the fins 212 remain unchanged during the narrowing process. Due to the fact that the narrowing processes are not selective, the trench floor surfaces adjacent to the fins are also affected. This means the first trenches 206 can be deeper than the second trenches 207. In a further exemplary embodiment (not shown), the same side wall of the individual mesas can in each case also be protected by the structured mask, i.e. always the left side of the mesas. In a further exemplary embodiment (not shown), a complete mesa can be protected from narrowing by the structured mask. As a result, for example, different fin widths can be realized.

FIG. 2E shows the intermediate product 250 of the method step 150 after the removal of the structured mask.

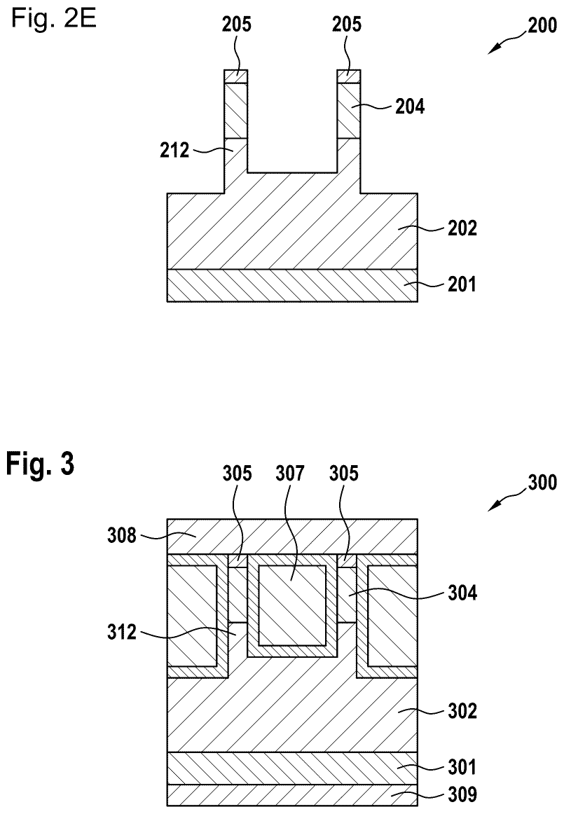

FIG. 3 shows the power semiconductor component 300 produced according to the present invention. The power semiconductor component 300 shows a FinMOSFET. The FinMOSFET comprises a drain electrode 309. A semiconductor substrate 301, for example SiC or GaN, is arranged on the drain electrode 309. A drift layer 302 is arranged on the semiconductor substrate 301. A preferably p-doped channel region 304 is arranged on the drift layer 302. A source region 305 is arranged on the channel region 304. A source electrode 308 is arranged on the source region 305. The fins 312 extend starting from the drift layer 302 up to the source electrode 308. A gate electrode 307 is electrically separated from the fins 312 by a gate dielectric 313.

In a further exemplary embodiment, the produced power semiconductor component can be a FinFET. The FinFET lacks the channel region 304 as shown in FIG. 3.

The FinMOSFET or FinFET produced according to the present invention is used, for example, in the electric drive train of an electric or hybrid vehicle, as well as in inverters for household appliances.

1-10. (canceled)

11. A method for producing a power semiconductor component having a plurality of fins, the method comprising the following steps:
creating a plurality of mesas starting from a front side of a semiconductor substrate into a drift layer of the semiconductor substrate by etching, wherein each mesa includes a top side that corresponds to a region of the front side of the semiconductor substrate, and each mesa is arranged between a first trench and a second trench, wherein the first trench includes a first trench bottom surface and the second trench comprises a second trench bottom surface, wherein each mesa includes a first side surface and a second side surface, wherein the first side surface corresponds to a first trench side surface of the first trench and the second side surface corresponds to a second trench side surface of the second trench, wherein each mesa has a width greater than 500 nm;
applying a mask layer to the top side, the first side surface, the second side surface, the first trench bottom surface; and the second trench bottom surface;
creating a structured mask by removing the mask layer in certain regions of the mask layer, so that an exposed surface is created, wherein the exposed surface includes the first side surface, the top side in certain regions and the first trench bottom surface;
creating fins by machining the exposed surface;
removing the structured mask; and
completing the power semiconductor component.

12. The method according to claim 11, wherein the semiconductor substrate includes SiC.

13. The method according to claim 11, wherein the mask layer includes SiN.

14. The method according to claim 11, wherein the fins are created using thermal oxidation.

15. The method according to claim 11, wherein the semiconductor substrate includes GaN.

16. The method according to claim 11, wherein the mask layer includes Ti or TiO2.

17. The method according to claim 11, characterized in that the fins are created using TMAH.

18. A power semiconductor component having a plurality of fins produced by:
creation of a plurality of mesas starting from a front side of a semiconductor substrate into a drift layer of the semiconductor substrate by etching, wherein each mesa includes a top side that corresponds to a region of the front side of the semiconductor substrate, and each mesa is arranged between a first trench and a second trench, wherein the first trench includes a first trench bottom surface and the second trench comprises a second trench bottom surface, wherein each mesa includes a first side surface and a second side surface, wherein the first side surface corresponds to a first trench side surface of the first trench and the second side surface corresponds to a second trench side surface of the second trench, wherein each mesa has a width greater than 500 nm;
application of a mask layer to the top side, the first side surface, the second side surface, the first trench bottom surface; and the second trench bottom surface;
creation of a structured mask by removing the mask layer in certain regions of the mask layer, so that an exposed surface is created, wherein the exposed surface includes the first side surface, the top side in certain regions and the first trench bottom surface;
creation of fins by machining the exposed surface;
removal the structured mask; and
completion of the power semiconductor component.

19. The power semiconductor component according to claim 18, wherein the power semiconductor component is a FinFET.

20. The power semiconductor component according to claim 18, wherein the power semiconductor component is a FinMOSFET.
